(19) United States
(12) Patent Application Publication
(10) Pub. No.: US 2002/0040992 A1
(43) Pub. Date: Apr. 11, 2002

(54) Nonvolatile semiconductor memory

(75) Inventors: Yukiko Manabe, Leuven (BE); Kousuke Okuyama, Kawagoe (JP); Tomohiko Oouchi, Fussa (JP); Takashi Takeuchi, Sagamihara (JP)

Correspondence Address: Miles & Stockbridge P.C., Suite 500, 1751 Pinnacle Drive,, McLean, VA, 22102-3833, US

(73) Assignee: Hitachi, Ltd.

(21) Appl. No.: 09/905,891

(22) Filed: Jul. 17, 2001

(30) Foreign Application Priority Data
Aug. 1, 2000 (JP) 2000-232657

(51) Int. Cl. H01L 29/76

(52) U.S. Cl. 257/314; 257/315; 257/324; 257/326

(57) ABSTRACT

The write performance and erasion performance of a nonvolatile semiconductor memory having as its memory elements MOSFETs in each of which a floating gate electrode is formed on each of the two sidewalls of a control gate electrode are to be improved, and the read performance is also to be improved. Part of the control gate electrode is extended above the floating gate electrodes on its two sidewalls. A source region and a drain region are formed alongside the outer boundaries of the floating gate electrodes so that electric charges can be separately injected into the two floating gate electrodes.

### BACKGROUND OF THE INVENTION

The present invention relates to a technique effectively applicable to nonvolatile memories which permit electrical writing of information to be stored and erasion thereof and, more particularly, applicable to multivalued nonvolatile memories which permit storage of two bits or more of information per memory element.

There is proposed a multivalued nonvolatile memory using as the memory element a metal oxide semiconductor field-effect transistor (MOSFET) of a double-layered gate structure having a control gate and a floating gate, wherein the threshold voltage is varied by a plurality of steps by varying the electric charge injected into the floating gate and two bits or more of information are enabled to be stored per memory element. A memory of such a formula is enabled to store two bits or more of information per memory element by varying the threshold voltage of the memory element by four levels.

On the other hand, there are also proposed, as alternatives to the aforementioned multivalued information memory element having a double-gate structure, memory elements wherein a floating gate electrode is formed on each of two sidewalls of a control gate electrode (e.g. Japanese Patent Laid-Open Nos. Hei 6(1994)-232412 and Hei 10(1998)-178116).

### SUMMARY OF THE INVENTION

In a nonvolatile memory wherein multivalued information is stored according to the level of the threshold voltage, it is necessary to control the distribution of individual threshold voltages, each corresponding to one unit of stored information, in a mutually distinguishable way. It is difficult, however, to control the distribution of threshold voltages in a narrow range because the operation to inject an electric charge into the floating gate fluctuates every time. Consequently, the overall range of threshold voltage distribution becomes wider than where one-bit (two-valued) information is to be stored. This means that the memory element whose threshold voltage has been raised to the highest level by the injection of negative charges is in a state wherein many negative charges have been injected into its floating gate. This results in a considerably high electric field applied to the gate insulating film of that memory element, and it is difficult to maintain that state for a long period, which means the trouble of poor retention performance.

The present inventors examined the aforementioned memory element in which a floating gate electrode is formed on each of the two sides of a control gate electrode, and found that the memory element structures disclosed in the prior art applications would not provide sufficient write and erasion performance or read performance.

An object of the present invention is to improve the write performance and erasion performance of a nonvolatile semiconductor memory having as its memory elements MOSFETs in each of which a floating gate electrode is formed on each of the two sidewalls of a control gate electrode.

Another object of the invention is to improve the read performance of a nonvolatile semiconductor memory having as its memory elements MOSFETs in each of which a floating gate electrode is formed on each of the two sidewalls of a control gate electrode.

The aforementioned and other objects and novel features of the invention will become more apparent from the description in this specification when taken in conjunction with the accompanying drawings.

What follows is a brief summary of typical aspects of the present invention disclosed in this application.

Thus, in the elements MOSFETs in each of which a floating gate electrode is formed on each of the two sidewalls of a control gate electrode, part of the control gate electrode is extended above the floating gate electrodes on its two sidewalls.

More specifically, the configuration is such that there are provided a control gate electrode formed over a semiconductor substrate via an insulating film, a pair of floating gate electrodes formed on the two sides of the control gate electrode via an insulating film each, and a source region and a drain region consisting of a pair of semiconductor regions each formed from underneath the floating gate on the surface of the semiconductor substrate toward its outside, wherein an eaves-shaped electrode is formed from both upper ends of the control gate electrode toward above the floating gate electrodes so as to cover over the floating gate electrodes and multivalued information is stored by the excess of charges accumulated in the floating gate electrodes.

The above-described means, wherein the eaves-shaped electrode is formed on two sides of the control gate electrode to cover over the floating gate electrodes, serves to increase a capacitance coupling ratio, i.e. the ratio of capacitance between the control gate electrode and the floating gate electrodes and that between the floating gate electrodes and the substrate, thereby to raise the voltage applied between the floating gate electrodes and the substrate compared with a memory element of a structure having no eaves-shaped part even if the voltage applied to the control gate electrode is the same, with the result that injection and extraction of electric charges into and out of the floating gate electrodes are facilitated and the write and erasion performances are improved.

Further, the memory element consisting of a MOSFET in which a floating gate electrode is formed on each of the two sidewalls of a control gate electrode has a configuration in which a source region and a drain region are formed along the outer boundaries of the floating gate electrodes so that electric charges can be separately injected into the two floating gate electrodes.

More specifically, there are provided a control gate electrode formed over a semiconductor substrate via an insulating film, a pair of floating gate electrodes formed on the two sides of the control gate electrode via an insulating film each, and a source region and a drain region consisting of a pair of semiconductor regions each formed from underneath the floating gate on the surface of the semiconductor substrate toward its outside, wherein the inner ends of the source region and of the drain region are formed in coordination with the outer boundaries of the floating gate electrodes.

As a memory element consisting of a MOSFET in which a floating gate electrode is formed on each of the two sidewalls of a control gate electrode, there is a configuration according to the prior art in which a source region and a drain region are formed in coordination with the outer boundary of the control gate electrode, i.e. with the inner boundaries of the floating gate electrodes. In this case, however, the control gate voltage versus drain current characteristic corresponding to the charge of the floating gate electrodes is distributed in a relatively narrow range as illustrated in FIG. 4(c) and difficult to distinguish, but in a structure in which the source region and the drain region are formed in coordination with the outer boundaries of the floating gate electrodes, the control gate voltage versus drain voltage characteristic corresponding to the charge of the floating gate electrodes is distributed in a relatively broad range as shown in FIG. 4(a). Therefore it is easier to distinguish, resulting in improved read performance.

Also, it is advantageous to form the eaves-shaped electrode from both ends of the upper part of the control gate electrode toward the upper right of the floating gate electrodes so as to cover over the floating gate electrodes. This serves to raise the capacitance coupling ratio, with the result that injection and extraction of electric charges into and out of the floating gate electrodes are facilitated and the write and erasion performances are improved.

The insulating films between the floating gate electrodes and the semiconductor substrate are foamed thinner than that between the control gate electrode and the semiconductor substrate. This facilitates injection of electric charges into the floating gate electrodes and to improve the write performance.

Furthermore, a nonvolatile semiconductor memory provided with a memory array in which memory elements of the above-described configuration are arranged in a matrix form, the control gate electrodes of the memory elements of the same row are connected to the same word line, and the source and drain regions of the memory elements of the same column are connected to the same bit line; an address decoder for selecting one or another of the word lines on the basis of an address signal supplied from outside; a sense-latch circuit for latching, when writing in, write data supplied from outside and applying to one or another of the bit lines an electric potential corresponding to the data and, when reading out, amplifying the potential of the bit line; and a control circuit for forming control signals for internal circuits on the basis of command codes supplied from outside and generating control signals for internal circuits including the address decoder and the sense-latch circuit can increase the memory capacity without having to expand the chip size because two bits of data can be stored per memory element, and moreover is simplified in the configurations of peripheral circuits around the memory array, including the sense-latch circuit, compared with a memory (semiconductor memory) storing multivalued information according to differences in threshold voltage.

According to another aspect of the invention described in this application, a multivalued nonvolatile semiconductor memory provided with memory elements each configured to store multivalued information according to any excess of charges accumulated in a pair of floating gate electrodes, and a first bit line is connected to one of a pair of semiconductor regions as the source region or the drain region of the memory element and a second bit line is connected to the other, and first and second latch circuits for latching write data are connectable to the first bit line and the second bit line, respectively. The first and second latch circuits respectively corresponding to the first bit line and the second bit line are caused to latch two-bit write data; in a state in which a high voltage is being applied to the word lines, a first voltage is applied to the first bit line correspondingly to the write data latched by the first latch circuit and a first writing is done on the second bit line by applying a second voltage irrespective of write data; after that, in a state in which a high voltage is being applied to the word lines, the first voltage is applied to the second bit line correspondingly to the write data latched by the second latch circuit; and a second writing is done on the first bit line by applying a second voltage irrespective of write data, so that two-bit data can be written into a single memory element in the two write operations.

The above-described means can cause write data entered from outside, without having to convert them in any way, to be latched by the latch circuits to be stored by the memory elements as multivalued information, and to simplify the configurations of peripheral circuits around the memory array.

Also, in a multivalued nonvolatile semiconductor memory provided with memory elements each configured to store multivalued information according to any excess of charges accumulated in a pair of floating gate electrodes, wherein a first bit line is connected to one of a pair of semiconductor regions as the source region or the drain region of the memory element and a second bit line is connected to the other, and first and second sense amplifier circuits are connectable to the first bit line and the second bit line, respectively: after precharging the first bit line to a first potential and setting word lines to a selection level, a first reading is done by activating the first sense amplifier circuit thereby to amplify the potential of the first bit line in a state wherein the second bit line is connected to a second potential point; then, after precharging the second bit line to the first potential and setting the word lines to a selection level, a second reading is done by activating the second sense amplifier circuit thereby to amplify the potential of the second bit line in a state wherein the first bit line is connected to the second potential point; and two-bit read data can be obtained in the two read operations. In this way, data amplified by the sense amplifier circuits can be externally outputted without having to convert them in anyway, and the configurations of peripheral circuits around the memory array can be simplified.

Further, in a multivalued nonvolatile semiconductor memory provided with memory elements each configured to store multivalued information according to any excess of charges accumulated in a pair of floating gate electrodes, wherein a first bit line is connected to one of a pair of semiconductor regions as the source region or the drain region of the memory element and a second bit line is connected to the other, a current detecting circuit is connected to the first bit line or the second bit line, and a switching means capable of applying a read voltage is connected to the second bit line or the first bit line: in a state wherein a read voltage is applied by the switching means to the second bit line or the first bit line, a word line is set to a selection level, the current flowing on the first bit line or the second bit line is detected by the current detecting circuit, and two-bit read data are obtained on the basis of the amperage thereby obtained. This enables stored data to be obtained in a single read operation, and the time taken to read out data is correspondingly shortened.

According to still another aspect of the invention, in fabricating a memory element configured to store multivalued information according to any excess of charges accumulated in a pair of floating gate electrode, an insulating film is formed over a semiconductor substrate and, after forming over it the main part of a control gate electrode, another insulating film is formed from the surface of the main part of the control gate electrode to the surface of the semiconductor substrate. After that, the insulating film is covered with a first electroconductive layer, which is then anisotropically etched to form floating gate electrodes on the sidewalls of the control gate electrode, followed by formation by ion implantation semiconductor regions which will constitute source and drain regions. Then, a second electroconductive layer is formed from the control gate electrode to above the floating gate electrodes to be in contact with the floating gate electrodes via the insulating film and in direct contact with the control gate electrode, and the second electroconductive layer is patterned to form the aforementioned eaves-shaped electrode. This enables, by merely adding a brief step, a control gate electrode having an eaves-shaped electrode to be formed and the capacitance coupling ratio to be increased, resulting in a nonvolatile semiconductor memory excelling in write and erasion performances.

Desirably, the control gate electrode of the memory element should be formed in the same process as the control gate electrode of some other MOS transistor than the memory element, the floating gate electrodes be formed in a state in which the other MOS transistor than the memory element is covered with an insulating film, and the semiconductor regions to constitute the source and drain regions of the memory element be formed in the same process as the source and drain regions of the MOS transistor other than the memory element. This enables the memory element and other MOS transistor than the memory element to be formed in many common processes, resulting in a reduced total chip cost.

### BRIEF DESCRIPTION OF THE DRAWINGS

FIG. 1 is a front view illustrating a sectional structure of a nonvolatile memory element, which is a first preferred embodiment of the present invention.

FIG. 2 is a front view illustrating a sectional structure of a nonvolatile memory element, which is a second preferred embodiment of the invention.

FIG. 3 is a front view illustrating a sectional structure of a nonvolatile memory element, which is a third preferred embodiment of the invention.

FIG. 4 consists of graphs showing the gate voltage versus drain current characteristic of a memory element having floating gate electrodes on sidewalls according to the invention and the gate voltage versus drain current characteristic of a memory element of the same type according to the prior art.

FIG. 5 is a sectional view illustrating in the sequence of steps a manufacturing method of a memory element, which is the third preferred embodiment of the invention.

FIG. 6 is a sectional view schematically illustrating the relationship among stored data, the bias voltage and the electric charges injected into the floating gate electrodes in a memory element embodying the invention.

FIG. 7 is a sectional view schematically illustrating the biased state in the memory element at the time of data erasion.

FIG. 8 is a flowchart showing the procedure of write processing in a semiconductor memory to which a memory element embodying the invention.

FIG. 9 is a sectional view schematically illustrating the biased state in the memory element at the time of data reading.

FIG. 10 is a block diagram illustrating an example of overall configuration of a flash memory as an example of semiconductor memory to which a memory element according to the invention can be effectively applied.

FIG. 11 is a circuit diagram schematically illustrating the configuration of a memory array and a sense-latch circuit.

FIG. 12 is a flowchart showing the procedure of read processing in a semiconductor memory to which a memory element embodying the invention.

FIG. 13 is a graph showing another example of the gate voltage versus drain current characteristic of a memory element according to the invention.

FIG. 14 is a circuit diagram schematically illustrating the configuration of a read circuit of a current sense system in a semiconductor memory in which a memory element according to the invention is used.

FIG. 15 is a circuit diagram schematically illustrating the configuration of the current detection/decision circuit in FIG. 14.

### DESCRIPTION OF THE PREFERRED EMBODIMENTS

Preferred embodiments of the present invention will be described below with reference to the accompanying drawings.

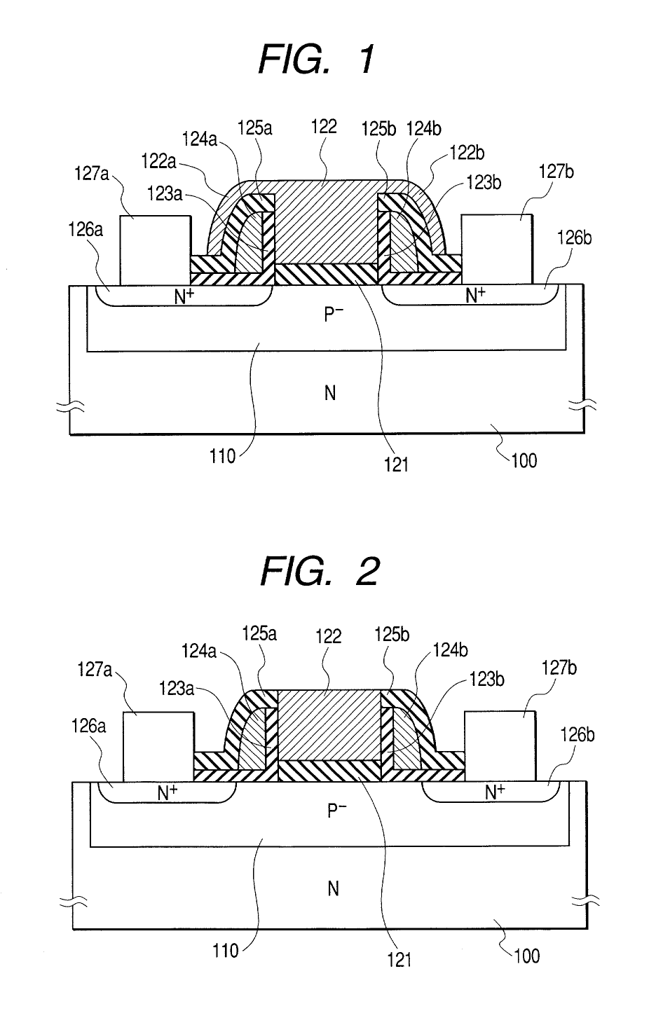

FIG. 1 illustrates a sectional structure of a nonvolatile memory element, which is a first preferred embodiment of the present invention. In the MOSFET constituting this embodiment, a control gate electrode 122 consisting of a polysilicon layer or the like is formed via a gate insulating film 121 over the surface of a P-type well region 110, formed over an N-type semiconductor substrate 100 of monocrystalline silicon or the like, and tunnel oxide films 123a and 123b are from the sidewalls of this control gate electrode 122 to the surface of the well region 110.

Over these tunnel oxide films 123a and 123b are formed a pair of floating gate electrodes 124a and 124b consisting or polysilicon or the like, positioned alongside the control gate electrode 122, and the surfaces of these floating gate electrodes 124a and 124b are covered by insulating films 125a and 125b. From both ends of the top of the control gate electrode 122 toward above the insulating films 125a and 125b over the surface of the floating gate electrodes 124a and 124b positioned alongside it, eaves-shaped electrode sections 122a and 122b extend so as to cover over the floating gate electrodes 124a and 124b. On the parts of the surface of the well region 110 alongside the control gate electrode 122 are formed diffusion layers 126a and 126b as source and drain regions in coordination with the outer boundaries of the control gate electrode 122, and over these diffusion layers 126a and 126b are formed source and drain electrodes 127a and 127b, respectively, in contact with the diffusion layers 126a and 126b.

FIG. 2 illustrates a sectional structure of a nonvolatile memory element, which is a second preferred embodiment of the invention. The MOSFET constituting this embodiment has a structure similar to that of FIG. 1. The differences from the embodiment shown in FIG. 1 consist in that, in the embodiment of FIG. 2, the eaves-shaped electrode sections 122a and 122b extending from both ends of the top of the control gate electrode 122 are absent and that the diffusion layers 126a and 126b as the source and drain regions formed over the surface of the well region 110 are formed in coordination not with the outer boundaries of the control gate electrode 122 but with those of the floating gate electrodes 124a and 124b. Thus in the MOSFET of FIG. 2, the diffusion layers 126a and 126b are formed in positions farther from the control gate electrode 122 than in the embodiment illustrated in FIG. 1.

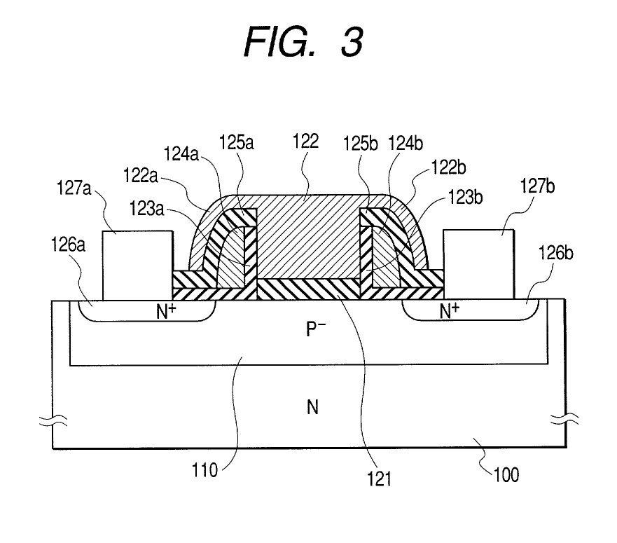

FIG. 3 illustrates a sectional structure of a nonvolatile memory element, which is a third preferred embodiment of the invention. The MOSFET constituting this embodiment has a structure similar to those of FIG. 1 and FIG. 2. The differences from the embodiment shown in FIG. 1 consist in that the diffusion layers 126a and 126b as the source and drain regions formed over the surface of the well region 110 are formed in coordination with the outer boundaries of the floating gate electrodes 124a and 124b as in the embodiment illustrated in FIG. 2. Thus in the MOSFET of FIG. 3, the diffusion layers 126a and 126b are formed in positions farther from the control gate electrode 122 than in the embodiment of FIG. 1.

On the other hand, the difference between the embodiment of FIG. 3 and that of FIG. 2 consists in that, in the embodiment illustrated in FIG. 3, the eaves-shaped electrode sections 122a and 122b extend from both ends of the top of the control gate electrode 122 to the insulating films 125a and 125b over the surface of the floating gate electrodes 124a and 124b positioned alongside it so as to cover over the floating gate electrodes 124a and 124b. The characteristics and advantages of the memory elements differently embodying the invention will be described below.

The MOSFET illustrated in FIG. 1 has a greater capacitance coupling ratio because the eaves-shaped electrode sections 122a and 122b extend from both ends of the top of the control gate electrode 122 so as to cover over the floating gate electrodes 124a and 124b. Thus, the ratio between a capacitance C2 between the control gate electrode 122 and the floating gate electrodes 124a and 124b and the sum of C2 and a capacitance C1 between the floating gate electrodes 124a and 124b and the substrate (C1+C2) (the ratio C2/(C1+C2)) is increased, with the result that the voltage applied between the floating gate electrodes and the substrate with the same voltage applied to the control gate electrode becomes greater, so that injection and extraction of electric charges into and out of the floating gate electrode are facilitated and the write and erasion performances are improved.

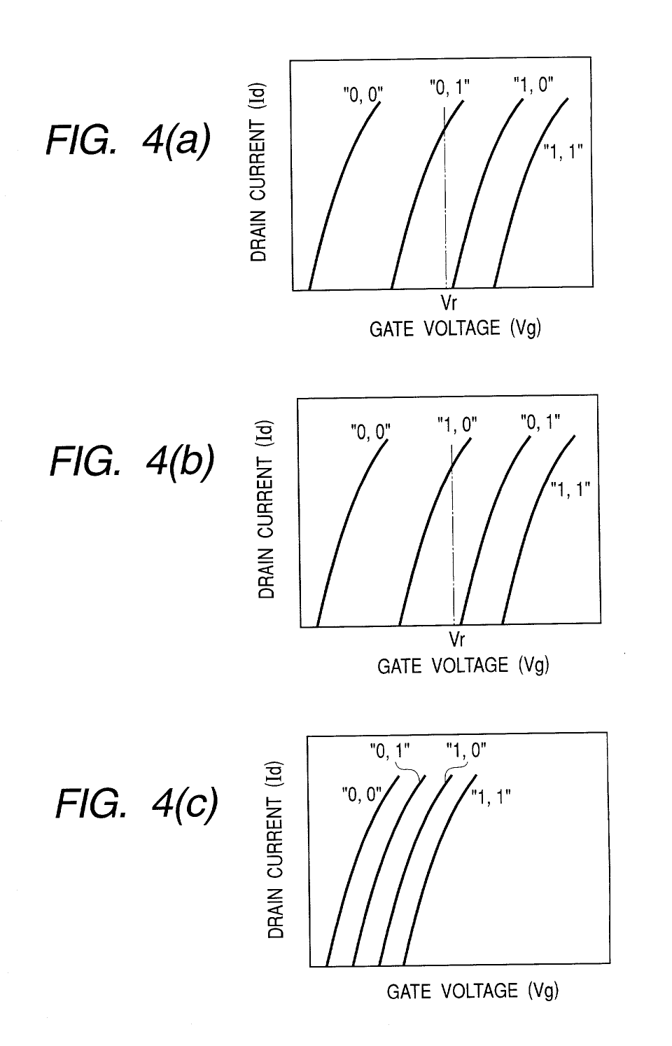

In the MOSFET of FIG. 2, the diffusion layers 126a and 126b as the source and drain regions as the source and drain regions are formed in coordination with the outer boundaries of the floating gate electrodes 124a and 124b. Thus, the diffusion layers 126a and 126b are formed farther away from the control gate electrode 122. If the diffusion layers 126a and 126b constitute the source and drain regions alongside the outer boundaries of the control gate electrode, i.e. the inner boundaries of the floating gate electrodes, the control gate voltage versus drain current characteristic corresponding to the charges of the floating gate electrodes will be distributed within a relative narrow range as shown in FIG. 4(c) and be difficult to distinguish. However, if the source and drain regions 124a and 124b are formed alongside the outer boundaries of the floating gate electrodes 124a and 124b as in the embodiment of FIG. 2, the control gate voltage versus drain current characteristic corresponding to the charges of the floating gate electrodes will be distributed over a relatively broad range as shown in FIGS. 4(a) or (b). Accordingly, it is easier to distinguish each, and accurate data can be read out with relative ease.

The MOSFET of FIG. 3 combines the advantages of both the embodiment illustrated in FIG. 1 and that in FIG. 2. Thus, the capacitance coupling ratio of the control gate electrode and the floating gate electrodes is increased, resulting in improved write and erasion performances and the distribution of the control gate voltage versus drain current performance in a relatively broad range, which facilitates distinction and makes possible reading of accurate data.

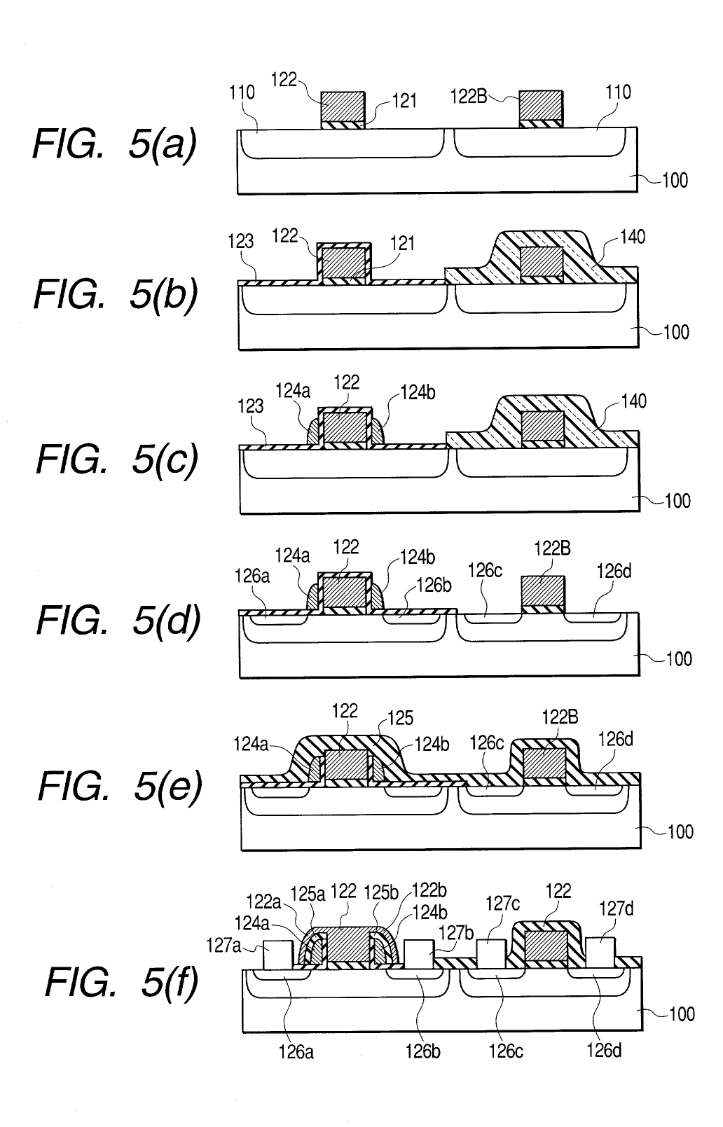

Next will be described with reference to FIG. 5 a production process for the MOSFET having on its sidewalls a pair of floating gate electrodes as in the above-cited embodiments, with a MOSFET of the structure of FIG. 3 taken up as an example. Incidentally, because a MOSFET as the memory element in the embodiments can be formed in parallel with a MOSFET as an active element constituting a peripheral circuit of the memory array, such as an address decoder, both will be illustrated side by side for the sake of convenience, and common steps of the process will also be described.

FIG. 5(a) illustrates a state in which the control gate electrode 122 consisting of a polysilicon layer and the like is formed via the gate insulating film 121 over the surface of the P-type well region 110 of a low impurity concentration formed over the N-type monocrystalline silicon substrate 100. The steps until this state is common for the sidewall type MOSFET as the memory element and for the MOSFET as an active element constituting a peripheral circuit, and they are formed at the same time.

After that, as shown in FIG. 5(b), in a state wherein the MOSFET part as an active element constituting a peripheral circuit is covered with a protective film 140 such as a silicon nitride film or a resist film, an oxide film 123 as thin as or thinner than the gate oxide film 121 is formed by either thermal oxidation or deposition from the surface top and sidewalls) of the gate electrode 122 of the MOSFET as the memory element toward the surface of the substrate 100. This oxide film 123 is an insulating film which constitutes the tunnel oxide film, and is formed in a suitable thickness for efficient performance of hot electron injection or electron extraction, resulting from an FN tunnel phenomenon, into or from the floating gate electrodes to be formed afterwards.

Next, with the MOSFET part as an active element constituting a peripheral circuit still being covered with the protective film 140, a low-resistance polysilicon layer containing impurities is formed by chemical vapor deposition (CVD) or otherwise over the oxide film 123, and the polysilicon layer is anisotropically etched. Then, the anisotropic etching works on the polysilicon more strongly in the longitudinal direction than in the lateral direction and, as shown in FIG. 5(c), residual polysilicon is formed on the sidewalls of the gate electrode 122 of the MOSFET as the memory element. In this embodiment, the residual polysilicon layers on the two sidewalls of this gate electrode 122 are utilized as the floating gate electrodes 124a and 124b.

Then, after removing the protective film 140 covering the MOSFET part as an active element constituting a peripheral circuit, the circumference of the element region is covered with a silicon nitride film or the like, N-type impurities are introduced into the surface of the substrate 100 by ion implantation, and the impurities are activated by heat treatment. Then, the gate electrode 122 functions as an ion implantation mask and, as shown in FIG. 5(d), the diffusion layers 126a and 126b as the source and drain are formed in the MOSFET part as the memory element in coordination with the outer boundaries of the floating electrodes 124a and 124b on the two sidewalls of the gate electrode 122. In the MOSFET part as an active element constituting a peripheral circuit, the diffusion layers 126c and 126d as the source and drain regions are formed in coordination with the gate electrode 122b.

Then, after removing the nitride film serving as an ion implantation mask, the insulating film 125 of silicon nitride or the like is formed all over by CVD or otherwise as shown in FIG. 5(e). The silicon nitride film is selectively etched to expose the upper surface of the control gate electrode 122, and a low-resistance polysilicon layer is formed all over it by CVD or otherwise. After that, this polysilicon layer is selectively etched to leave it only in the part from above the gate electrode 122 of the MOSFET as the memory element toward where it meets the sidewalls. This results in formation of the eaves-shaped electrode sections 122a and 122b so as to cover over the floating gate electrodes 124a and 124b from both ends of the top of the gate electrode 122 toward the sidewall insulating films 125a and 125b.

After that, an insulating film of silicon nitride or the like is formed all over again by CVD or otherwise, contact holes are formed in the positions of the substrate matching these insulating film diffusion layers 126a and 126b and, after forming an electroconductive layer of aluminum or the like all over by vapor deposition or otherwise, patterning is carried out to form the source and drain electrodes 127a and 127b as shown in FIG. 5(f). At this time, in the MOSFET part as an active element constituting a peripheral circuit, the source and drain electrode 127c and 127d connected to the diffusion layers 126c and 126d as the source and drain regions are formed at the same time, and aluminum wiring for inter-element or inter-circuit connection is formed elsewhere.

Next will be described the methods to write, read and erase two-bit information into and out of memory elements consisting of MOSFETs having the structure of the embodiments described above.

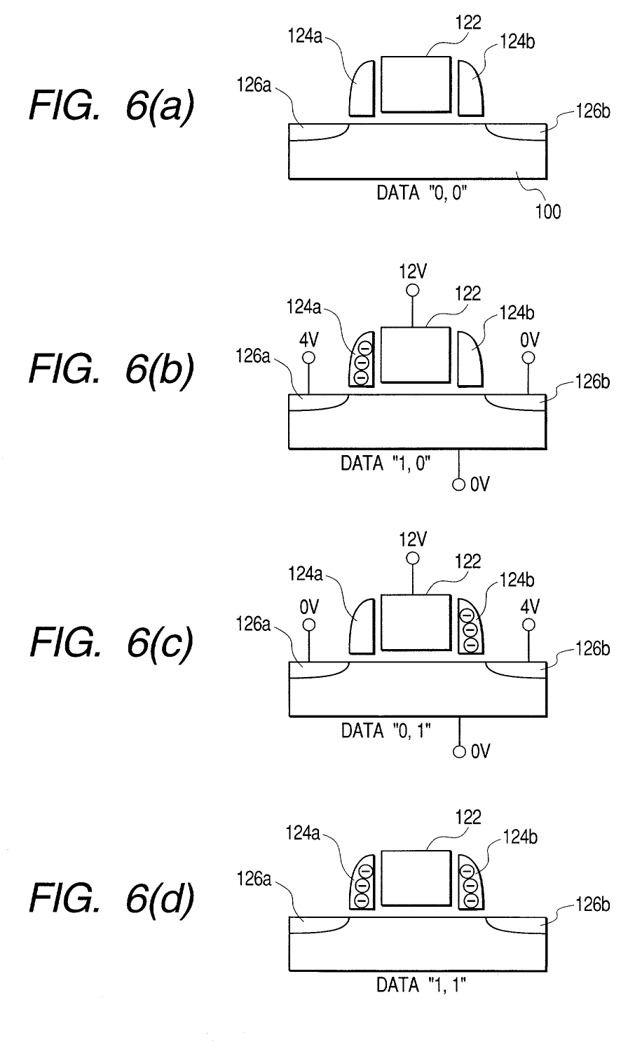

Writing of information into a memory element according to the invention is accomplished by injecting electric charges into the floating gate electrodes 124a and 124b on both sides of the control gate. More specifically, four states including a state in which no negative charge is injected into either of the left and right floating gate electrodes 124a and 124b as shown in FIG. 6(a), a state in which a negative charge is injected into only the left side floating gate electrode 124a as shown in FIG. 6(b), a state in which a negative charge is injected into only the right side floating gate electrode 124b as shown in FIG. 6(c), and a state in which negative charges are injected into both of the left and right floating gate electrodes 124a and 124b as shown in FIG. 6(d) are caused to be stored correspondingly to two-bit write data “0, 0”, “1, 0”, “0, 1” and “1, 1”, respectively.

Although the possible relationship of correspondence between the different states of the memory element and data is not limited to the above-described but may be in any other way, supposing the above-stated relationship relatively facilitates writing of data as will be explained below. Thus, where it is desired to inject a negative charge into the left side floating gate electrode 124a, a high voltage of 12 V, for instance, is applied to the control gate electrode 122 while applying a voltage of 4 V, for instance, is applied to the diffusion layer 126a on the side where charge injection is desired and a ground potential (0 V) is applied to the diffusion layer 126b on the other side as shown in FIG. 6(b). Then, electrons shift from the diffusion layer 126b as the source to the diffusion layer 126a as the drain and are accelerated by the voltage between the source and the drain to generate hot electrons in the vicinity of the drain. The generated hot electrons are injected into the floating gate electrode 124a on the left side.

On the other hand, where it is desired to inject a negative charge into the right side floating gate electrode 124b a high voltage of 12 V, for instance, is applied to the control gate electrode 122 while applying a voltage of 4 V, for instance, is applied to the diffusion layer 126b on the side where charge injection is desired and a ground potential (0 V) is applied to the diffusion layer 126a on the other side as shown in FIG. 6(b). Then, electrons shift from the diffusion layer 126a as the source to the diffusion layer 126b as the drain and are accelerated by the voltage between the source and the drain to generate hot electrons in the vicinity of the drain. The generated hot electrons are injected into the floating gate electrode 124a.

Therefore, if the state of FIG. 6(b) is matched with write data “1, 0”, that of FIG. 6(c) with write data “0, 1”, and that of FIG. 6(d) with write data “1, 1”, by applying a 4 V voltage to the corresponding one of the diffusion layers 126a and 126b according to whether or not either one of the two bits of the two-bit write data, an electric charge can be injected into the corresponding desired floating electrode.

To add, in a system of injection into a floating gate electrode by injecting hot electrons generated by flowing a drain current as described above, it is impossible to inject electric charges into the left and right floating gate electrodes 124a and 124b at the same time. Then, in writing data “1, 1”, it is possible create a state in which electric charges are injected into the left and right floating gate electrodes 124a and 124b as shown in FIG. 6(d) by separately carrying out injection of an electric charge into the left side floating gate electrode 124a corresponding to the write data “1, 0” and injection of an electric charge into the right side floating gate electrode 124b corresponding to the write data “0 ,1”.

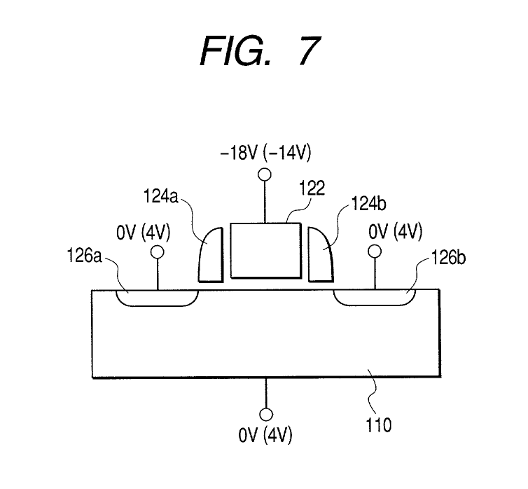

On the other hand, erasion of data, i.e. extraction of electric charges from the floating gate electrodes 124a and 124b, is accomplished by applying a negative high voltage, such as −18 V, to the control gate electrode 122 and a ground potential (0 V) to the diffusion layers 126a and 126b and the well region 110 as shown in FIG. 7. In this way, as the electrons accumulated in the floating gate electrodes 124a and 124b by an FN tunnel phenomenon are extracted into the diffusion layers 126a and 126b, there is no need to work separately on the two floating gate electrodes as in the case of writing. Moreover, such data erasion can be carried out simultaneously from a plurality of memory elements sharing the same well region such as a group of memory elements connected to the same word line (hereinafter to be referred to as a sector).

To add, the bias voltages to be possibly applied to the memory element for data erasion are not limited to the combination of −18 V and 0 V, but erasion can as well be accomplished by applying bias voltages totaling 18 V, such as a negative high voltage, e.g. −14 V, to the control gate electrode 122 and 4 V to the diffusion layers 126a and 126b and the well region 110.

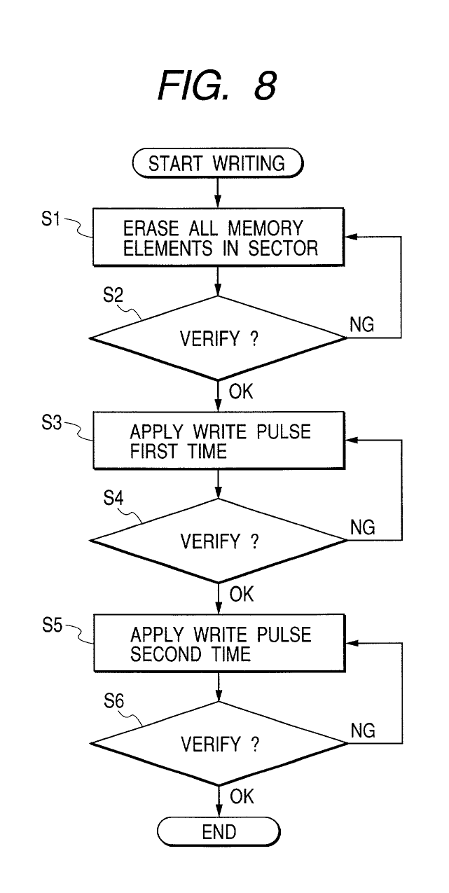

Now, an example of procedure of writing into a nonvolatile memory using the above-described system of injecting into floating gate electrodes hot electrons generated by flowing a drain current will be described with reference to the flowchart of FIG. 8.

Incidentally, the flowchart in FIG. 8 is started by the inputting of a write command from, for instance, an external CPU to the nonvolatile memory. The control circuit, upon deciphering the input command and perceiving it as a write command, places all the memory elements in the sector to be written into (hereinafter to be referred to as the selected sector) in an erased state (a state corresponding to data “0, 0”) by applying bias voltages to them as shown in FIG. 7 (step S1). Then, it is judged whether or not the threshold voltage Vth of every memory element in the selected sector is lower than an erase verify voltage VWE (step S2). If there is any memory element, even one, whose threshold voltage is higher than VWE, process returns to step S1 to repeat erasion.

If it is judged at step S2 that the threshold voltage Vth of every memory element is lower than VWE, the process goes ahead to step S3, where, according to the write data, a first writing is done by applying bias voltages, such as shown in FIG. 6(b), if the first bit is “1”, to each memory element to raise its threshold voltage. Then, it is judged whether or not the threshold voltage Vth of the memory element, into which the data have been written, in the selected sector has become higher than a write verify voltage VWV1 (step S4) If there is found any memory element whose threshold voltage is below VWV1 even after writing, the process returns to step S3 to repeat writing. The memory elements whose threshold voltage is changed by this writing are only those corresponding to write data of “1, 0” or “1, 1”.

Next, the process goes ahead to step S5, where, according to the write data, a second writing is done by applying bias voltages, such as shown in FIG. 6(c), if the first bit is “1”, to each memory element to raise its threshold voltage. Then, it is judged whether or not the threshold voltage Vth of the memory element, into which the data have been written, in the selected sector has become higher than a write verify voltage VWV2 (step S6). If there is found any memory element whose threshold voltage is below VWV2 even after writing, the process returns to step S5 to repeat writing. The memory elements whose threshold voltage is changed by the second writing are only those corresponding to write data of “0, 1” or “1, 1”. If at step S6 above the threshold voltage Vth of every memory element to be written into has become higher than the verify voltage VWE2, write processing for the whole sector is completed. Where writing into a plurality of sectors is to be done consecutively, the process returns to step S1 to repeat the above-described operation.

Next, the operation to read out of a memory element according to the invention will be described.

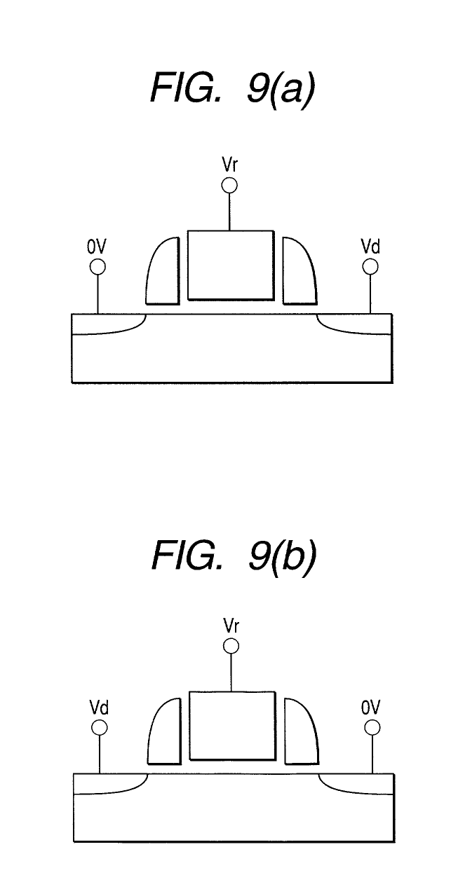

In a memory element into whose floating gate electrodes 124a and 124b electric charges were injected by the above-described write operation, when a voltage Vg applied to the control gate electrode 122 is varied by applying 0 V to the diffusion layer 126a and a read drain voltage Vd of 1 to 3 V, for instance, to the diffusion layer 126b as shown in FIG. 9(a), a drain current Id as shown in FIG. 4(a) flows according to the floating gate electrode to which data to be stored, i.e. an electric charge, was injected. On the other hand, when the voltage Vg applied to the control gate electrode 122 is varied by applying the read drain voltage Vd to the diffusion layer 126a and 0 V to the diffusion layer 126b as shown in FIG. 9(b), a drain current Id as shown in FIG. 4(b) flows according to the floating gate electrode to which data to be stored, i.e. an electric charge, was injected.

As comparison of (a) and (b) in FIG. 4 clearly reveals, when the data stored are “0, 0” or “1, 1”, the drain current characteristic will remain the same even if the bias voltages to the diffusion layers 126a and 126b are reversed. On the contrary, when the data stored are “0, 1” or “1, 0”, the drain current characteristic will also be reversed if the bias voltages to the diffusion layers 126a and 126b are reversed. Thus, when the read drain voltage Vd is applied to the diffusion layer on the side of the floating gate electrode to which an electric charge was injected, more of the drain current Id will flow if the gate voltage is the same.

Therefore, it is possible to determine which of the four types a given set of data stored belongs to by setting the voltage Vg applied to the control gate electrode 122 to a value like Vr between the two drain current curves corresponding to the data stored of “0, 1” and “1, 0” in FIG. 4, reversing the relationship between the diffusion layers 126a and 126b as shown in FIGS. 9(a) and (b), performing a read operation twice, and checking whether or not a drain current has flowed. Table 1 shows the relationship between the data stored and the presence of absence of a drain current in a state in which bias currents have been applied in the relationship of FIG. 9(a) (biased state 1) and in a state in which bias currents have been applied in the relationship of FIG. 9(b) (biased state 2). In Table 1, a ∘ mark denotes the presence of a drain current flow, and a x mark, the absence of a drain current flow. Table 1

TABLE 1

| Data stored | “0, 0” | “0, 1” | “1, 0” | “1, 1” |
|---|---|---|---|---|
| Biased state 1 | ∘ | ∘ | x | x |
| Biased state 2 | ∘ | x | ∘ | x |

It is seen from Table 1 that: where the bias relationship is reversed as in FIG. 9(a) and (b) and the read operation is performed twice: if the drain current flows on both occasions, the data stored in the memory element are “0, 0”; if the drain current flows on the first occasion but not on the second, the data stored in the memory element are “0, 1”; if the drain current does not flow on the first occasion but does on the second, the data stored in the memory element are “1, 0”; or if the drain current does not flow on either occasion, the data stored in the memory element are “1, 1”. To add, the presence or absence of a drain current can be detected by comparing the read current for the memory element directly with a reference current, but it can as well be detected, as will be described afterwards, by comparing a voltage converted from the read current with a reference voltage or in a precharging system in which, after precharging one of the bit lines, it is checked whether or not the potential on the bit line has varied with the gate of the memory element set to a selection level.

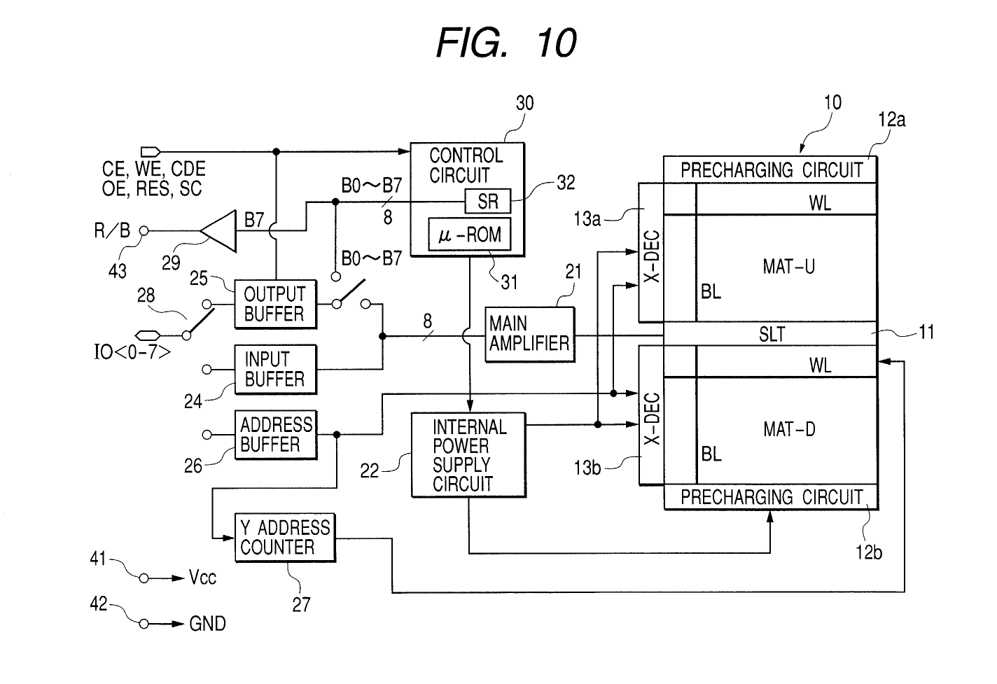

FIG. 10 is a block diagram illustrating an example of flash memory as an example of semiconductor memory to which a nonvolatile memory element according to the invention is applied. The flash memory embodying the invention in this way is configured of a multivalued memory capable of storing two-bit memory per memory cell and formed over a single semiconductor chip of monocrystalline silicon or the like, though not specifically limited to this configuration.

In this embodiment, a memory array 10 is configured of two mats MAT-U and MAT-D, between which is arranged a circuit, connected to bit lines BL in one or the other of the mats and having sense-amplifying and latching functions (hereinafter to be collectively referred to as the sense-latch circuit and denoted by SLT in the drawings). Outside each mat, i.e. on the other side from the sense-latch circuit (SLT) 11 with the bit lines BL in-between, there is arranged a precharging circuit for precharging the bit lines. Sense amplifiers in the sense-latch circuit 11 detect and latch read data by amplifying the difference in potential between the bit lines of the upper mat and those of the lower mat. The bit lines on the side of the selected mat are precharged immediately before reading to a potential, such as a source voltage, VPc and the bit lines on the non-selected side, whose potential is compared with that on the selected side, are precharged to a potential, such as Vpc/, though the possible disposition is not limited to this.

In each of the memory mats MAT-U and MAT-D, memory cells each consisting of a MOSFET of the above-described embodiment, having a control gate and floating gates on its sidewalls, are arranged in a matrix form, control gates of memory cells of the same rows are consecutively formed to constitute a word line WL, drains of memory cells of the same column are connected to a common first bit line BLa, and sources of memory cells of the same column is connected to a common second bit line BLb.

In the memory array 10, address decoders (word decoders) 13a and 13b of the X system are provided to match the memory mats MAT-U and MAT-D, respectively. Each of the decoders 13a and 13b contains a word drive circuit for driving one of the word lines WL in the corresponding memory mat to a selection level according to the result of decoding.

An address decoder circuit of the Y system and a column switch selectively turned on and off by this decoder are configured integrally with the sense-latch circuit 11. Reference numeral 21 denotes a main amplifier for further amplifying the output of a sense amplifier in the sense-latch circuit 11, amplified by the sense amplifier and selected by a column decoder and the column switch.

The flash memory embodying the invention in this manner is provided with a control circuit (sequencer) 30 which successively forms control signals to interpret commands provided from control units, including an external microprocessor, and to execute processing as required by each command, supplies them to different circuits within the memory, and is so configured as to decipher each command as it is supplied and to automatically respond, though the possible configuration is not limited to this. The control circuit 30 is provided with, for instance, a read only memory (ROM) 31, in which a series of micro-commands required for the execution of commands are stored, and is configured to successively execute the micro-commands and to form control signals for different circuits within the chip. The control circuit 30 is further provided with a status register 32 to reflect the internal state.

The multivalued flash memory of this embodiment is also provided with, among others, an internal power supply circuit 22 for generating a high voltage for use in writing or erasion; an input buffer circuit 24 for taking in write data signals and commands entered from outside; an output buffer circuit 25 for outputting data signals read out of the memory array and supplying to the outside the contents of the status register 32; an address buffer circuit 26 for taking in address signals entered from outside; and an address counter 27 for taking in entered address signals, counting up and generating addresses of the Y system.

The input buffer circuit 24, the output buffer circuit 25 and the address buffer circuit 26 are connected to common input/output terminals I/00 through I/07 via a change-over switch 28, and are so configured as to input and output data, commands and address signals on a time sharing basis. The configuration is such that input data supplied from outside at the time of writing are taken into the input buffer circuit 24, and latched via the main amplifier 21 by the sense amplifier selected within the sense-latch circuit 11. Then, in this embodiment, the bits of write data entered in eight-bit units are paired into two bits each, of which one is latched by the sense amplifier matched with the first bit line in the memory array 10 and the other, by the sense amplifier matched with the second bit line in the memory array 10.

The internal power supply circuit 22 comprises a reference power generating circuit for generating a voltage to which a write voltage and the like refer; an internal power generating circuit for generating voltages required within the chip, on the basis of a source voltage Vcc supplied from outside, including a write voltage, an erasion voltage, a read voltage and a verify voltage; a power switching circuit for selecting a desired voltage out of these voltages according to the operating state of the memory and supplying it to the memory array 10 or the address decoder 13a or 13b; and a power supply control circuit for controlling these circuits. To add, in FIG. 1, reference numeral 41 denotes a source voltage terminal to which the source voltage Vcc is applied from outside, and 42, another source voltage terminal (ground terminal) to which a ground potential Vss is applied.

Control signals that may be entered into the flash memory of this embodiment from an external CPU or the like include, for example, a reset signal RES, a chip selection signal CE, a write control signal WE, an output control signal OE, a command enable signal indicating whether a given input is a command, data or an address, and a system clock SC. Commands and addresses are taken into the input buffer circuit 24 and the address buffer circuit 26 in accordance with the command enable signal CDE and the write control signal WE, respectively, while write data are taken into the input buffer circuit 24 in response to the inputting of the system clock SC when the command enable signal CDE indicates a command or a data input and in synchronism with this clock. Furthermore, in this embodiment, there is provided an output buffer 29 for supplying an external terminal 43 with a ready/busy signal R/B indicating whether or not access from outside is possible according to a prescribed bit of the status register 32 reflecting the internal state of the memory.

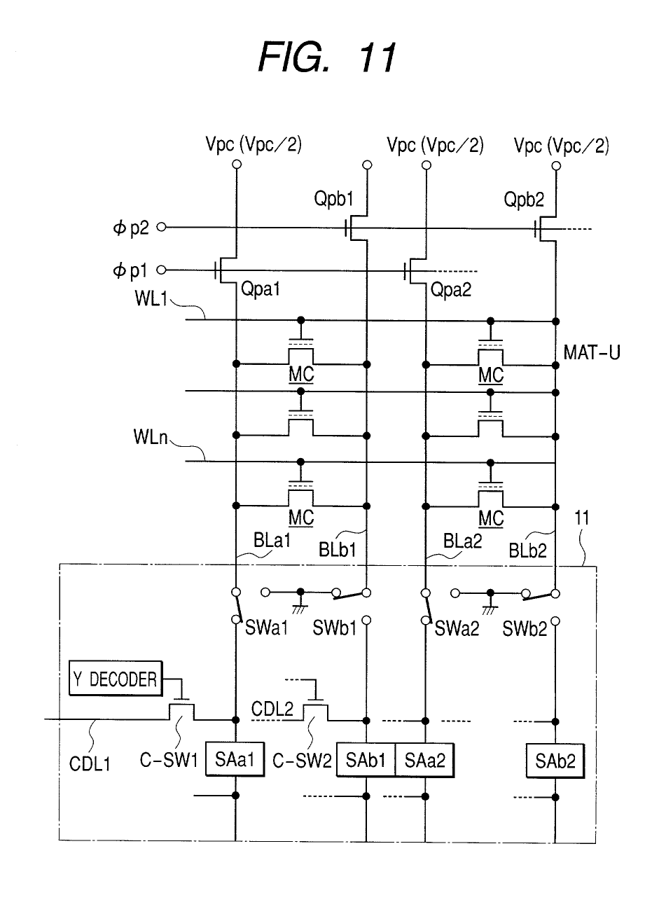

FIG. 11 schematically illustrates the configuration of the memory array 10 and the sense-latch circuit 11 where the above-described precharging system is used for data reading. Within the memory array 10, a plurality of memory cells MC are arranged in a matrix form; word lines WL to each of which the control gates of memory cells of the same row are connected are arranged to cross first bit lines BLa to each of which the drains of memory cells of the same column are connected and second bit lines BLb to each of which the sources of memory cells of the same column are connected, and the first bit lines BLa and the second bit lines BLb are arranged in parallel with each other. To add, in FIG. 11, thebit lines are distinguished among one another by suffixing numerals 1, 2, . . . to the reference signs, such as BLa1, BLa2, . . . with a different numeral assigned to each memory column. The same applies to sense amplifiers SAa and SAb to be described afterwards.

On the other side of the first bit lines BLa and the second bit lines BLb than the sense-latch circuit 11, there are provided precharging MOSFETs Qpa and Qpb, which alternately precharge the first bit lines BLa and the second bit lines BLb at the time of reading according to the two read operations. The first bit lines BLa and the second bit lines BLb are provided with switches SWa and SWb, and ground potentials are applied to the first bit lines BLa or the second bit lines BLb on the non-precharged side at the time of reading by the switches SWa and SWb.

At one end of each of the bit lines BLa and BLb is respectively connected a latch type sense amplifier SAa or SAb having both the sense-amplifying function for amplifying the potential of the bit line and a data latching function. Between the input/output terminals of these sense amplifiers SAa and SAb and common data lines CDL1 and CDL2 are provided column switches C-SW1 and C-SW2 which are selectively turned on by a signal resulting from the decoding of a column address.

Data writing into the sense-latch circuit 11 of such a configuration begins with having the sense amplifiers SAa and SAb respectively matching the first bit line BLa and the second bit line BLb latch each set of two-bit write data and applying a high voltage, such as 12 V, to the word lines. Then, a write voltage is applied to the first bit line BLa according to the write data latched by the sense amplifier SAa; when the write data bit is “0”, 0 V is applied or when it is “1”, 4 V is applied. At this time, 0 V is applied to the other second bit line BLb irrespective of the write data latched by the sense amplifier SAb. This results in the generation of the bias state shown in FIG. 6(b), and an electric charge is injected into the floating gate electrode 124a.

Next, a high voltage such as 12 V is applied to the word lines, and a write voltage is applied to the second bit line BLb according to the write data latched by the sense amplifier SAb; when the write data bit is “0”, 0 V is applied or when it is “1”, 4 V is applied. At this time, 0 V is applied to the other first bit line BLa irrespective of the write data latched by the sense amplifier SAa. This leads to the generation of the bias state shown in FIG. 6(c), and an electric charge is injected into the floating gate electrode 124b. The results of these two write operations are that: when the write data latched by the sense amplifiers SAa and Sab are “0, 0”, no electric charge is injected into either of the floating gate electrodes 124a and 124b by either operation; when the data are “1, 0”, the first write operation injects an electric charge into the floating gate electrode 124a; when the data are “0, 1”, the second write operation injects an electric charge into the floating gate electrode 124b; and when the data are “1, 1”, the first and second write operations inject electric charges into the floating gate electrodes 124a and 124b, respectively. This disposition can realize accumulated charge states of the floating gate electrodes 124a and 124b matching the two-bit write data as illustrated in FIGS. 6(a) through 6(d). When data are to be erased, a negative high voltage (e.g. −18 V) is applied to the word lines WL (control gate), and negative charges are extracted by an FN tunnel phenomenon from the floating gates of the memory cell to lower their threshold voltages by applying 0 V to the first bit line BLa and the second bit line BLb.

It is possible to configure the flash memory of this embodiment to permit choice between storage of two-valued data or storage of four-value data in each memory cell. Where two-valued data are to be stored in each memory cell, the sense amplifier in the sense-latch circuit 11 is caused to transfer every other unit of write data to inject an electric charge into only one of the floating gate electrodes in each memory element, and at the time of reading, the sense amplifier matched with either the first bit line BLa or the second bit line BLb is caused to amplify the potential on the bit line. Electric charges based on the same data can as well be injected into both floating gate electrodes of the memory element. This would serve to enhance the reliability of data.

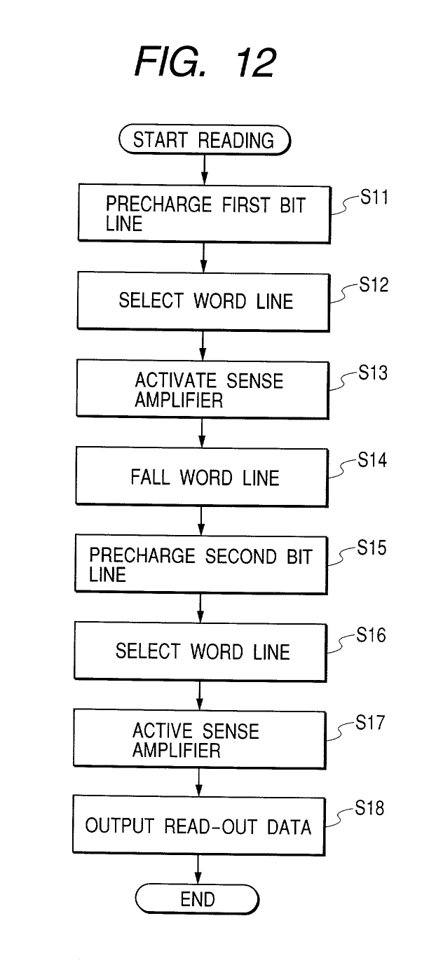

Next will be described the data reading procedure in the above-described embodiment of the precharging system with reference to the flowchart of FIG. 12.

The flowchart in FIG. 12 is started by the inputting of a read command from, for instance, an external CPU to the nonvolatile memory though the possible procedure is not limited to this. The control circuit, upon deciphering the input command and perceiving it as a read command, takes in an address signal and precharges the first bit line BLa in the memory mat on the selected side to a potential Vpc of, for instance, 1 V (step S11). It also precharges the first bit line BLa in the memory mat on the non-selected to Vpc/2, i.e. half of Vpc.

Next, the address signal that has been taken in is decoded and the word lines WL are set to a selection level, such as 3 V (step S12). As a result, a drain current flows in some memory elements while it does not in others because the threshold voltage differs from one memory element to another according to the presence or absence of charges in the pair of floating gate electrode. The precharge on a first bit line BLa to which a memory element whose threshold voltage is low and in which a drain current flows is connected flows to a second bit line, and its potential drops to the ground level. On the other hand, the precharge on a first bit line BLa to which a memory element whose threshold voltage is low and in which no drain current flows remains as it is, and its potential is maintained at the Vpc level.

In this state, the control circuit activates the sense amplifier SAa connected to the precharged first bit line BLa (step S13). Then the potential 0 V or Vpc of the first bit line BLa is compared with the precharged potential Vpc/2 of the matching bit line in the memory mat on the non-selected side, and the difference in potential is amplified. The amplified read data are latched as they are by the sense amplifier SAa.

Then, the control circuit, after once causing the potential of the selected word line to fall, precharges the second bit line BLb in the memory mat on the selected side to Vpc (steps S14 and S15). It also precharges the second bit line BLb in the memory mat on the non-selected side to Vpc/2.

Next, the same word line WL is set to the selection level again (step S16). As a result, a drain current flows in some memory elements while it does not in others because the threshold voltage differs from one memory element to another according to the presence or absence of charges in the pair of floating gate electrode. Then, the precharge on a second bit line BLb to which a memory element in which a drain current flows is connected flows to a second bit line, and its potential drops to the ground level. On the other hand, the precharge on a first bit line BLa to which a memory element in which no drain current flows remains as it is, and its potential is maintained at the Vpc level.

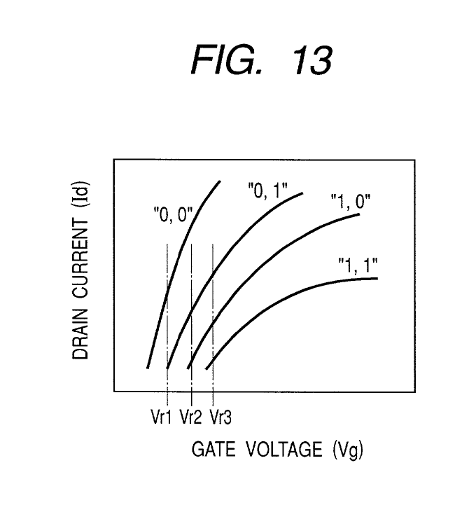

In this state, the control circuit activates the sense amplifier SAb connected to the precharged second bit line BLb (step S17). Then the potential 0 V or Vpc of the second bit line BLb is compared with the precharged potential Vpc/2 of the matching bit line in the memory mat on the non-selected side, and the difference in potential is amplified. The amplified read data are latched as they are by the sense amplifier SAb. Thus, the data read out and latched in the sense amplifier are the same as they were written in. For instance, they are delivered in eight-bit units to the main amplifier, amplified and supplied outside by an output buffer (step S18) The sense-latch circuit 11 in a case in which a bit line precharge system is applied and the method of reading data thereby have been described so far. Such a data reading method is effective where the gate voltage versus drain current characteristics of the memory element are dispersed to some extent according to the data stored as shown in FIGS. 4(a) and 4(b). On the other hand, a MOSFET having sidewall type floating gate electrodes like the embodiments shown in FIG. 1 through FIG. 3 may manifest, depending on its structure and the voltage applied thereto, gate voltage versus drain current characteristics according to the data stored as shown in FIG. 13. Thus, it is a case in which the current characteristic curves are gently sloped and overlap one another. Two methods are conceivable for reading out data stored in a memory element having such gate voltage versus drain current characteristics.

A first method is to read out data a plurality of times while changing the read gate voltage (word line potential) in three stages such as Vr1, Vr2 and Vr3, latch the data thereby obtained and make judgment on that basis. In this case, the three read operations take a longer time than otherwise.

A second one is a current sensing method by which a prescribed gate voltage (word line potential) is applied, and the amperage of the drain current then flowing in the memory element is detected to make judgment on the data. This method has the advantage of a shorter length of time taken, because data can be distinguished by a single write operation. An example of implementing this current sensing method will be described below.

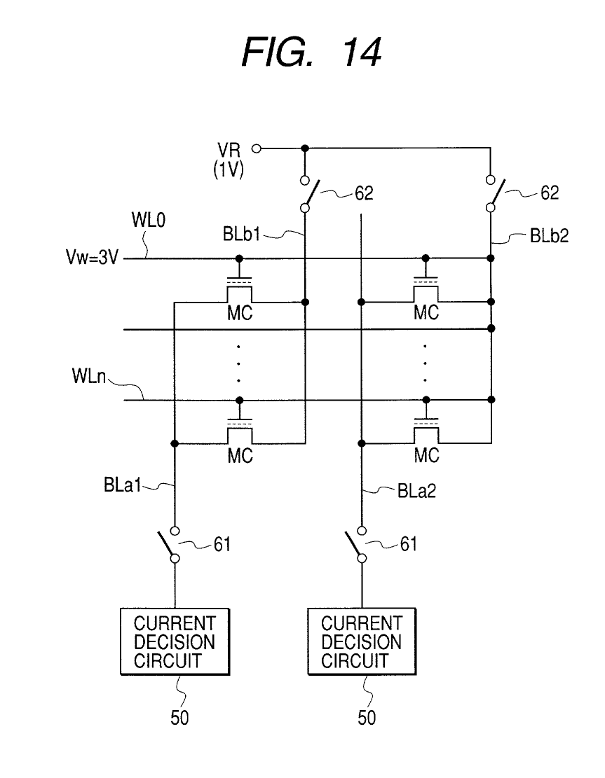

For the current sensing method, a current detection/decision circuit 50 shown in FIG. 14, a switch 61 for connecting a first bit line BLa to the current detection/decision circuit 50 at the time of reading and a switch 62 for connecting a read voltage supply terminal VR, which provides a reading voltage, such as 1 V, to a second bit line BLb are provided for each memory column in addition to the circuits for writing shown in FIG. 11.

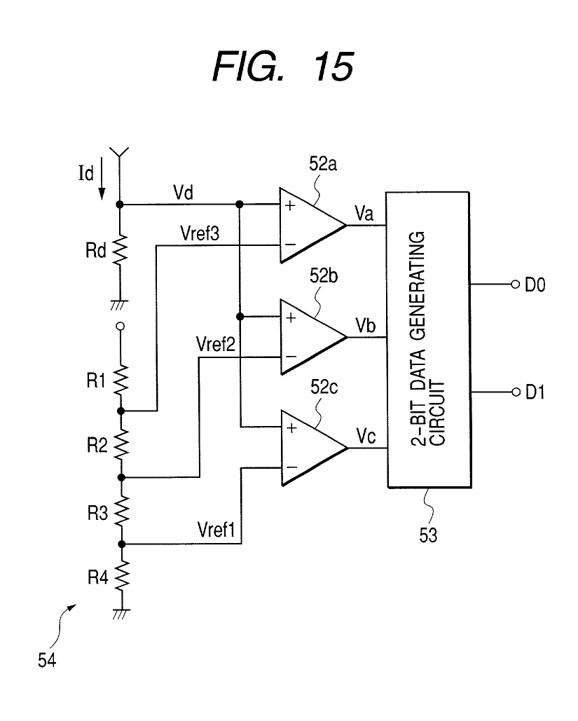

FIG. 15 illustrates the configuration of the above-mentioned current detection/decision circuit 50. The current detection/decision circuit 50 of FIG. 15 is configured of a resistance Rd for converting a read current Id flowing out of a first bit line BLa into a voltage; a resistance type voltage divider 51 consisting of series resistances R1, R2, R3 and R4 and generating comparison voltages Vref1, Vref2 and Vref3 to be compared with a voltage Vd resulting from conversion by the resistance Rd; voltage comparators 52a, 52b and 52c of each of which one input terminal is given the common inputting of the voltage Vd resulting from conversion by the resistance Rd and the other input terminal is given the inputting of the comparison voltage Vref1, Vref2 or Vref3, respectively; and a two-bit data generating circuit 53 for generating two-bit data on the basis of the outputs of these voltage comparators 52a, 52b and 52c.

The voltage comparators 52a, 52b and 52c compare the voltage Vd resulting from conversion by the resistance Rd and the comparison voltages Vref1, Vref2 and Vref3 and, if Vd is higher than Vref3, all the outputs of the voltage comparators 52a, 52b and 52c will take on a high level. Or if Vd is lower than Vref3 and higher Vref2, the output of the voltage comparator 52a will take on a low level and those of 52b and 52c will take on a high level. Or if Vd is lower than Vref2 and higher than Vref1, the outputs of the voltage comparator 52a and 52b will take on a low level and that of 52c will take on a high level. Further, if Vd is lower than Vref1, all the outputs of the voltage comparators 52a, 52b and 52c will take on a low level.

Table 2 shows the relationship between the outputs Va, Vb and Vc of the voltage comparators 52a, 52b and 52c and the two-bit output data D0 and D1 of the data generating circuit 53.

TABLE 2

| Comparator outputs | | | |
|---|---|---|---|
| Va | Vb | Vc | 2-bit data |
| H | H | H | “0, 0” |
| H | H | L | “0, 1” |
| H | L | L | “1, 0” |
| L | L | L | “1, 1” |

In this embodiment, it is possible to give decision on the data stored by a single read operation, resulting in the advantage of a shorter length of time taken to read data.

Whereas the invention accomplished by the present inventor has been described so far with reference to preferred embodiments thereof, obviously the invention is not limited to these embodiments, but can be modified in various ways without deviating from the spirit of the invention. For instance, although the embodiments were described to be comprising memory elements each consisting of a MOSFET having a structure in which floating gate electrodes are formed on a pair of sidewalls opposite each other with a control gate electrode between them, the invention can as well be applied to memory elements each consisting of a MOSFET having a structure in which floating gate electrodes are formed on not only a pair of right and left sidewalls opposite each other with a control gate electrode between them but also another pair of sidewalls opposite each other in tandem. In this case, three-bit information can be stored in each memory element. Furthermore, the number of bits of information that can be stored per memory element can be increased by using memory elements each consisting of a MOSFET having a structure in which the control gate electrode is formed in a hexagonal or octagonal, instead of rectangular, shape and floating gate electrodes are formed on each pair of opposite sidewalls.

With reference to the preferred embodiments, a flash memory of a type in which the threshold voltage of memory cells is lowered by erasion and raised by writing was also described, the invention can as well be applied to a flash memory of a type in which the threshold voltage of memory cells is raised by erasion and lowered by writing. Positive charges (holes), instead of negative charges, can as well be accumulated in the floating gate electrodes. Further, instead of writing (injecting electric charges) into memory elements matching data “1”, data can be written (electric charges injected) into memory elements matching data “0”.

Although the foregoing description of the invention accomplished by the present inventor mainly referred to its application to a nonvolatile memory having as its memory elements consisting of sidewall type MOSFETs in which floating gate electrodes are formed on the two sidewalls of a control gate electrode, which constitutes the background of the invention, the invention is not limited to this application, but can be utilized for nonvolatile memories in general using as their memory elements each having a MOSFET in which a plurality of floating gate electrodes are provided separately from a control gate electrode, such as underneath the control gate electrode.

Benefits provided by typical aspects of the invention disclosed in this application are summarized below.

Thus, according to the invention, a nonvolatile semiconductor memory having as its memory elements each consisting of a MOSFET in which floating gate electrodes are formed on both sidewalls of a control gate electrode can improve its write and erasion performances as well as the read performance.

What is claimed is:

1. A multivalued nonvolatile semiconductor memory provided with memory elements each having a control gate electrode formed over a semiconductor substrate via an insulating film, a pair of floating gate electrodes formed on the two sides of the control gate electrode via an insulating film each, and a source region and a drain region consisting of a pair of semiconductor regions each formed from underneath said floating gate on the surface of said semiconductor substrate toward its outside, wherein:
an eaves-shaped electrode is formed from both upper ends of said control gate electrode toward above said floating gate electrodes so as to cover over said floating gate electrodes, and multivalued information is stored by the excess of charges accumulated in said floating gate electrodes.

2. A multivalued nonvolatile semiconductor memory provided with memory elements each having a control gate electrode formed over a semiconductor substrate via an insulating film, a pair of floating gate electrodes formed on the two sides of the control gate electrode via an insulating film each, and a source region and a drain region consisting of a pair of semiconductor regions each formed from underneath said floating gate on the surface of said semiconductor substrate toward its outside, wherein:
the inner ends of said source region and drain region are formed in coordination with the outer boundaries of said floating gate electrodes.

3. The multivalued nonvolatile semiconductor memory according to claim 2, wherein an eaves-shaped electrode is formed from both upper ends of said control gate electrode toward above said floating gate electrodes so as to cover over said floating gate electrodes, and multivalued information is stored by the excess of charges accumulated in said floating gate electrodes.

4. The nonvolatile semiconductor memory according to claim 3, wherein the insulating films between said floating gate electrodes and said semiconductor substrate are formed thinner than the insulating film between said control gate electrode and said semiconductor substrate.

5. The multivalued nonvolatile semiconductor memory according to claim 4, provided with a memory array in which memory elements of said configuration are arranged in a matrix form, the control gate electrodes of the memory elements of the same row being connected to the same word line, and the source and drain regions of the memory elements of the same column being connected to the same bit line; an address decoder for selecting one or another of said word lines on the basis of an address signal supplied from outside; a sense-latch circuit for latching, when writing in, write data supplied from outside and applying to one or another of said bit lines an electric potential corresponding to the data and, when reading out, amplifying the potential of said bit line; and a control circuit for forming control signals for internal circuits on the basis of command codes supplied from outside and generating control signals for internal circuits including said address decoder and sense-latch circuit.

6. A multivalued information writing method for use in a multivalued nonvolatile semiconductor memory provided with memory elements each having a control gate electrode formed over a semiconductor substrate via an insulating film, a pair of floating gate electrodes formed on the two sides of the control gate electrode via an insulating film each, and a source region and a drain region consisting of a pair of semiconductor regions each formed from underneath said floating gate on the surface of said semiconductor substrate toward its outside, wherein: multivalued information is stored by the excess of charges accumulated in said floating gate electrodes; a first bit line is connected to one of a pair of semiconductor regions as the source region or the drain region of the memory element and a second bit line is connected to the other; and first and second latch circuits for latching write data are connectable to the first bit line and the second bit line, respectively, said writing method comprising the steps in which:
the first and second latch circuits respectively corresponding to said first bit line and second bit line are caused to latch two-bit write data; in a state in which a high voltage is being applied to the word lines, a first voltage is applied to the first bit line correspondingly to the write data latched by said first latch circuit and a first writing is done on the second bit line by applying a second voltage irrespective of write data; after that, in a state in which a high voltage is being applied to the word lines, the first voltage is applied to the second bit line correspondingly to the write data latched by said second latch circuit; and a second writing is done on the first bit line by applying a second voltage irrespective of write data, so that two-bit data can be written into a single memory element in said two write operations.

7. A multivalued information reading method for use in a multivalued nonvolatile semiconductor memory provided with memory elements each having a control gate electrode formed over a semiconductor substrate via an insulating film, a pair of floating gate electrodes formed on the two sides of the control gate electrode via an insulating film each, and a source region and a drain region consisting of a pair of semiconductor regions each formed from underneath said floating gate on the surface of said semiconductor substrate toward its outside, wherein: multivalued information is stored by the excess of charges accumulated in said floating gate electrodes; a first bit line is connected to one of a pair of semiconductor regions as the source region or the drain region of the memory element and a second bit line is connected to the other; and first and second sense amplifier circuits are connectable to the first bit line and the second bit line, respectively, said reading method comprising the steps in which:
after precharging said first bit line to a first potential and setting word lines to a selection level, a first reading is done by activating the first sense amplifier circuit thereby to amplify the potential of the first bit line in a state wherein said second bit line is connected to a second potential point; then, after precharging said second bit line to the first potential and setting the word lines to a selection level, a second reading is done by activating the second sense amplifier circuit thereby to amplify the potential of the second bit line in a state wherein the first bit line is connected to the second potential point; and two-bit read data are obtained in said two read operations.

8. A multivalued information reading method for use in a multivalued nonvolatile semiconductor memory provided with memory elements each having a control gate electrode formed over a semiconductor substrate via an insulating film, a pair of floating gate electrodes formed on the two sides of the control gate electrode via an insulating film each, and a source region and a drain region consisting of a pair of semiconductor regions each formed from underneath said floating gate on the surface of said semiconductor substrate toward its outside, wherein: multivalued information is stored by the excess of charges accumulated in said floating gate electrodes; a first bit line is connected to one of a pair of semiconductor regions as the source region or the drain region of the memory element and a second bit line is connected to the other; a current detecting circuit is connected to said first bit line or second bit line, and a switching means capable of applying a read voltage is connected to the second bit line or the first bit line, said reading method further comprising the steps in which:
in a state wherein a read voltage is applied by said switching means to the second bit line or the first bit line, a word line is set to a selection level, the current flowing on said first bit line or second bit line is detected by said current detecting circuit, and two-bit read data are obtained on the basis of the amperage thereby obtained.

9. A manufacturing method for a multivalued nonvolatile semiconductor memory, wherein: in fabricating each memory element, according to claim 3, an insulating film is formed over a semiconductor substrate; after forming over it the main part of a control gate electrode, another insulating film is formed from the surface of the main part of the control gate electrode to the surface of the semiconductor substrate; after that, said insulating film is covered with a first electroconductive layer, which is then anisotropically etched to form floating gate electrodes on the sidewalls of said control gate electrode, followed by formation by ion implantation semiconductor regions which will constitute source and drain regions; then a second electroconductive layer is formed from said control gate electrode to above the floating gate electrodes to be in contact with the floating gate electrodes via the insulating film and in direct contact with the control gate electrode; and the second electroconductive layer is patterned to form said eaves-shaped electrode.

10. The manufacturing method for a multivalued nonvolatile semiconductor memory, according to claim 9, wherein: the control gate electrode of said memory element is formed in the same process as the control gate electrode of some other MOS transistor than the memory element; the floating gate electrodes are formed in a state in which the other MOS transistor than said memory element is covered with an insulating film; and the semiconductor regions to constitute the source and drain regions of said memory element are formed in the same process as the source and drain regions of the MOS transistor other than the memory element.
